(19) United States
(12) Patent Application Publication
(10) Pub. No.: US 2025/0336740 A1
(43) Pub. Date: Oct. 30, 2025

(54) ELECTRONIC DEVICES AND A METHODS OF MANUFACTURING ELECTRONIC DEVICES

(71) Applicant: Amkor Technology Singapore Holding Pte. Ltd., Singapore (SG)

(72) Inventors: Kyoung Yeon Lee, Incheon (KR); Se Man Oh, Incheon (KR); Jae Beom Shim, Incheon (KR)

(73) Assignee: Amkor Technology Singapore Holding Pte. Ltd., Singapore (SG)

(21) Appl. No.: 18/648,765

(22) Filed: Apr. 29, 2024

(51) Int. Cl. H01L 23/31; H01L 23/00; H01L 23/373; H01L 23/498; H01L 25/065

(52) U.S. Cl. CPC H01L 23/3128; H01L 23/3737; H01L 23/49816; H01L 23/49822; H01L 24/05; H01L 24/13; H01L 25/0655; H01L 2224/05008; H01L 2224/05025; H01L 2224/13009; H01L 2224/13025; H01L 2924/01029; H01L 2924/06; H01L 2924/15311; H01L 2924/182

(57) ABSTRACT

In one example, an electronic device comprises a substrate comprising a top side, a bottom side, a dielectric structure, and a conductive structure, a first electronic component over the top side of the substrate and coupled with the conductive structure, wherein the first electronic component comprises a first side facing the substrate and a second side facing away from the substrate, an encapsulant over the top side of the substrate and covering a lateral side of the first electronic component, a lid over the top side of the substrate and over the first electronic component, and an adhesive between the second side of the first electronic component and an inner side of the lid. Other examples and related methods are also disclosed herein.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2H show cross-sectional views of an example method for manufacturing an example electronic device.

FIG. 3 shows a cross-sectional view of an example electronic device.

FIGS. 4A to 4H show cross-sectional views of an example method for manufacturing an example electronic device.

FIGS. 5A to 5H show cross-sectional views of an example method for manufacturing an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or.” As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” and so on, can be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” can be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” can be used to describe two elements directly contacting each other or describe two elements indirectly coupled by one or more other elements. As used herein, the term “coupled” can refer to a mechanical coupling or an electrical coupling.

### DESCRIPTION

In one example, an electronic device comprises a substrate comprising a top side, a bottom side, a dielectric structure, and a conductive structure, a first electronic component over the top side of the substrate and coupled with the conductive structure, wherein the first electronic component comprises a first side facing the substrate and a second side facing away from the substrate, an encapsulant over the top side of the substrate and covering a lateral side of the first electronic component, a lid over the top side of the substrate and over the first electronic component, and an adhesive between the second side of the first electronic component and an inner side of the lid.

In another example, a method to manufacture an electronic device comprises providing a lid comprising a first side and a second side, providing an adhesive on the first side of the lid, providing a first electronic component on the first side of the lid on the adhesive, providing an encapsulant on the first side of the lid and covering a lateral side of the first electronic component, and providing a substrate over the encapsulant, over the first electronic component, and over the lid, wherein the substrate comprises a dielectric structure and a conductive structure, and wherein the first electronic component is coupled with the conductive structure.

Other examples are included in the present disclosure. Such examples may be found in the figures, in the claims, or in the description of the present disclosure.

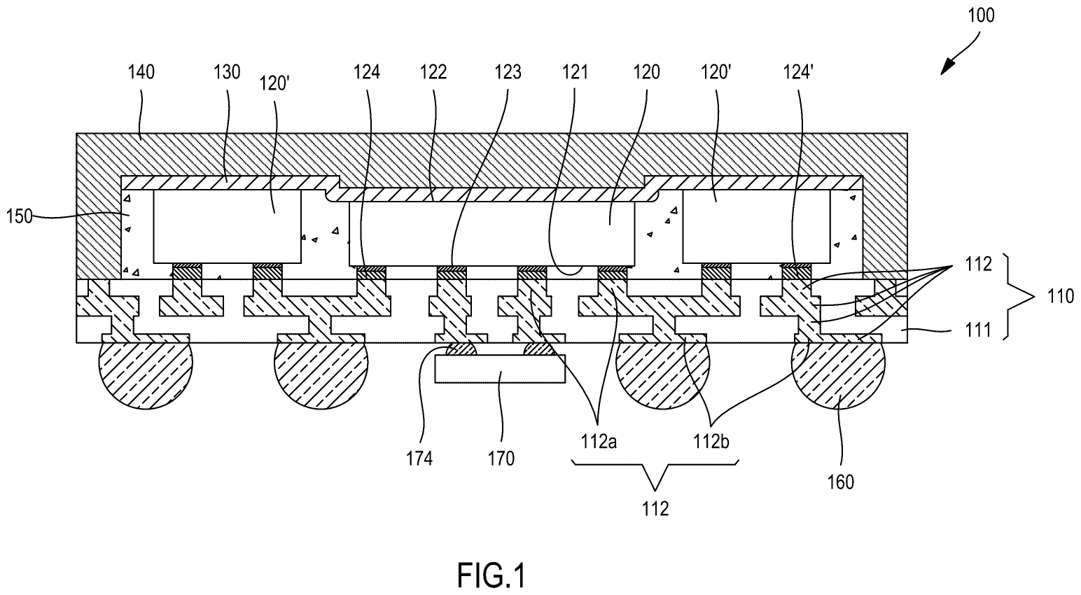

FIG. 1 shows a cross-sectional view of an example electronic device 100. In the example shown in FIG. 1, electronic device 100 can comprise substrate 110, electronic components 120, 120′, adhesive material 130, lid 140, encapsulant 150, and external interconnects 160. In some examples, electronic device 100 can comprise electronic component 170.

Substrate 110 can have a top side and a bottom side and can comprise dielectric structure 111 and conductive structure 112. Conductive structure 112 can comprise substrate inward terminals 112a and substrate outward terminals 112b.

Electronic component 120 can be over the top side of substrate 110 and can comprise first side 121 and second side 122 opposite to first side 121. Electronic component 120 can comprise contact pad 123 on first side 121. First side 121 of electronic component 121 can face substrate 110 and second side 122 of electronic component 120 can face away from substrate 110. Electronic component 120 can comprise connector 124 coupled to or in contact with contact pad 123. Contact pad 123 and connector 124 can be coupled with conductive structure 112. Electronic components 120′ and 170 can comprise connectors 124′ and 174, respectively. Encapsulant 150 can cover the top side of substrate 110 and can cover a lateral side of electronic component 120. Lid 140 can be over the top side of substrate 110 and over electronic component 120. Adhesive material 130 can be between second side 122 of electronic component 120 and an inner side of lid 140. In some examples, lid 140 can directly contact conductive structure 112 or can directly contact dielectric structure 111. In some examples, lid 140 can be coupled to conductive structure 112 or can be coupled to dielectric structure 111. In some examples, a bottom side of lid 140 (e.g., a bottom side of the lid sidewall) can be coplanar with a bottom side of encapsulant 150, and a top side of conductive structure 112 can be coplanar the bottom side of lid 140. In some examples, the bottom side of lid 140 can be coplanar with a top side of dielectric structure 111.

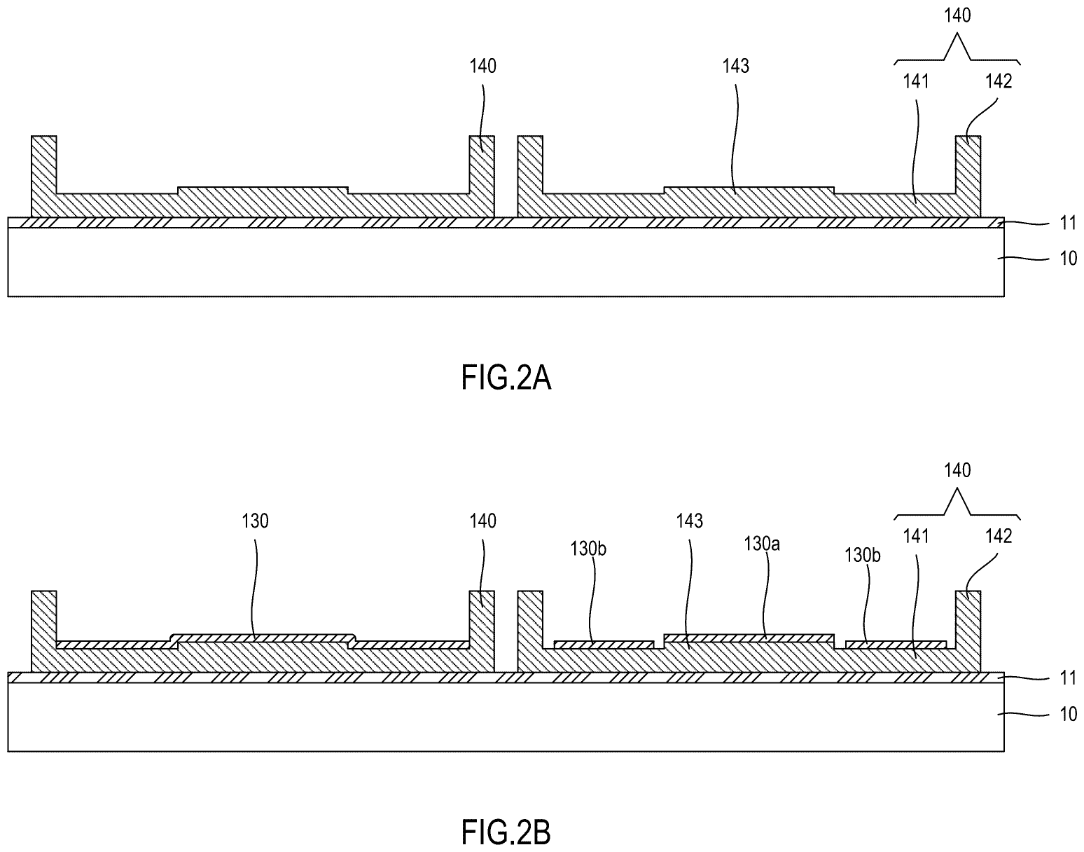

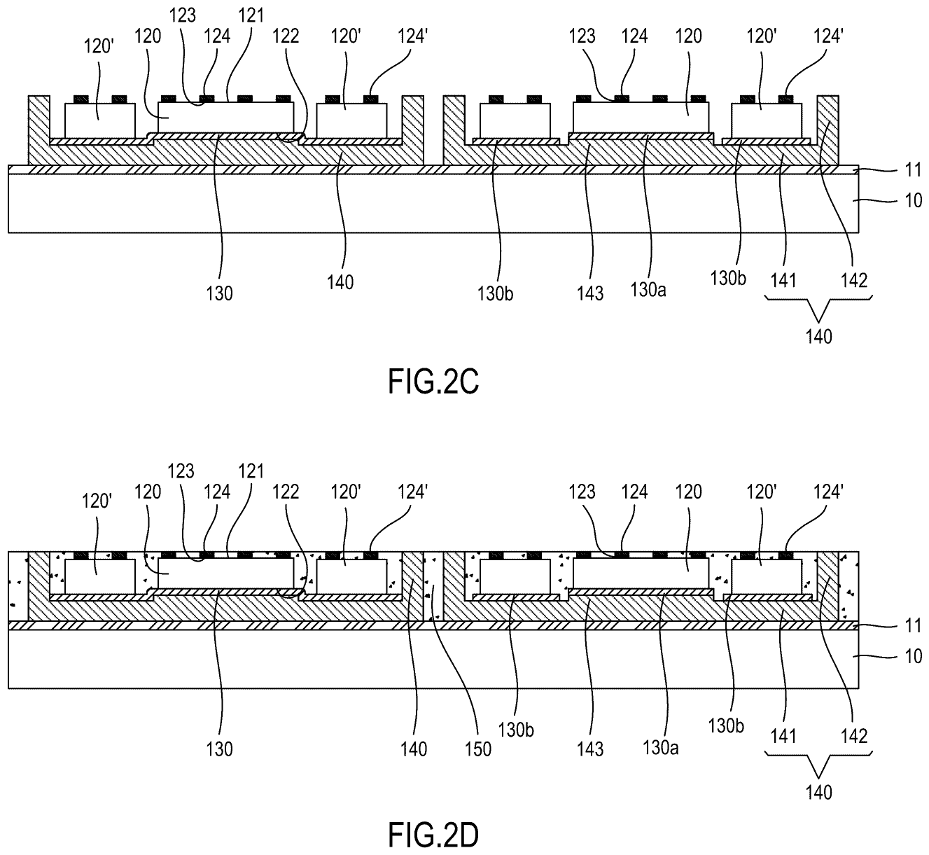

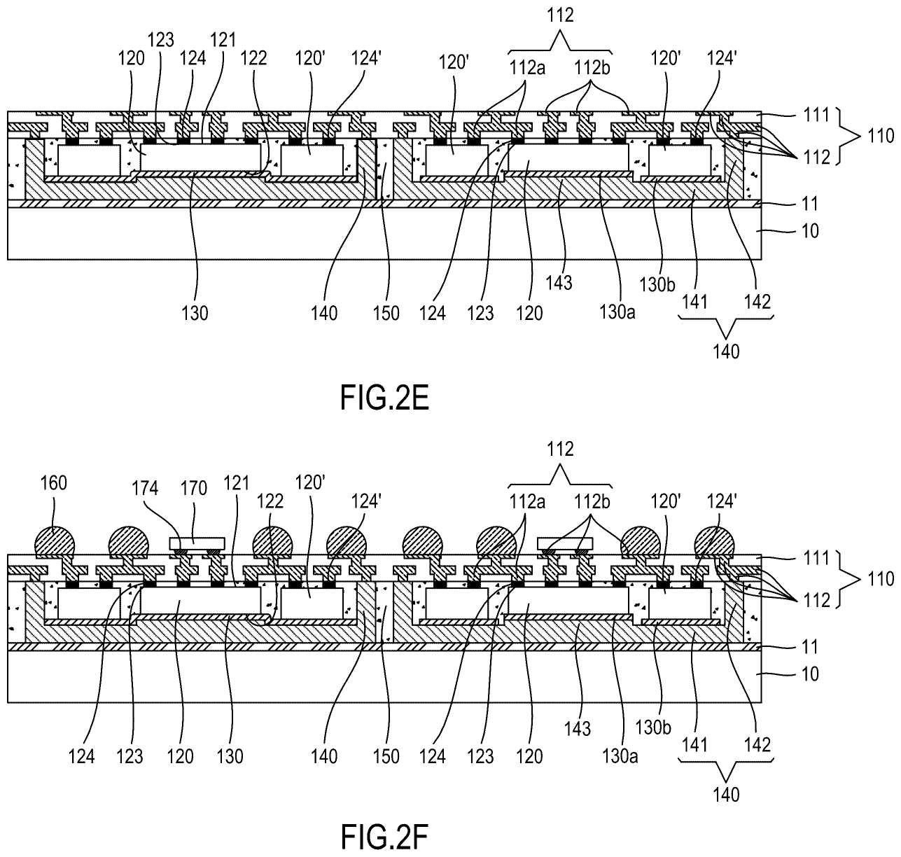

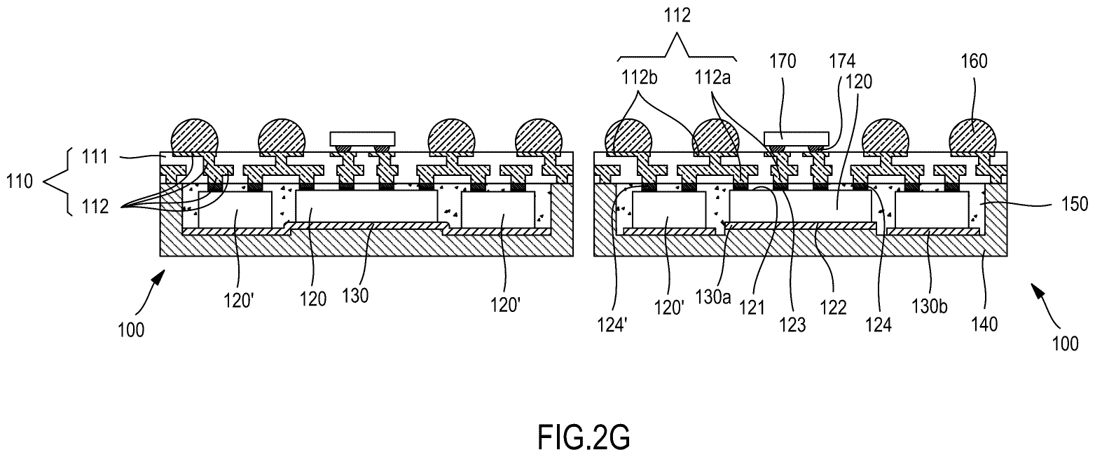

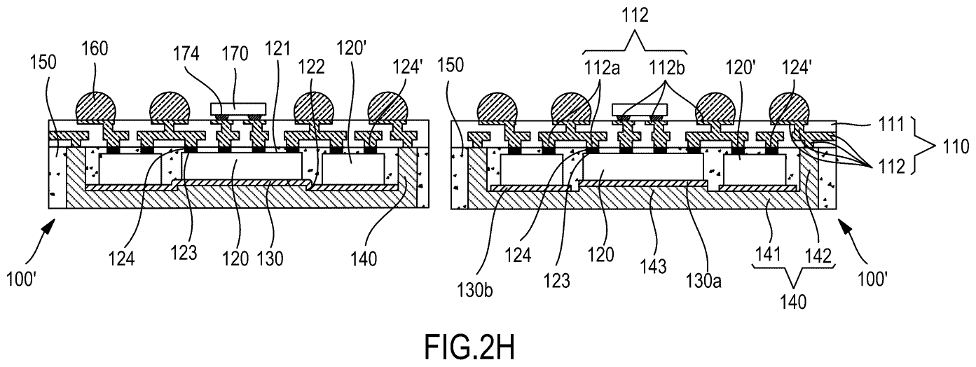

FIGS. 2A to 2H show cross-sectional views of an example method for manufacturing an example electronic device, such as electronic device 100 in FIG. 1. FIG. 2A shows a cross-sectional view of electronic device 100 at an early stage of manufacture. In the example shown in FIG. 2A, lid 140 can be provided on a surface of carrier 10. Lid 140 can be attached to the upper side of carrier 10. Carrier 10 can comprise temporary bonding layer 11 provided on the upper side. Lid 140 can be attached to temporary bonding layer 11 of carrier 10.

Lid 140 can include top plate 141 and sidewalls 142. In some examples, top plate 141 can be a square or rectangular plate. In some examples, lid 140 can include four sidewalls 142 bent and/or extending from the edges of top plate 141. Lid 140 can be oriented such that the outer (or second) side of top plate 141 can be attached to carrier 10 through temporary bonding layer 11. For example, multiple lids 140 can be attached to carrier 10 and spaced apart from each other over carrier 10.

Lid 140 can have a cavity produced by top plate 141 and sidewalls 142. In some examples, lid 140 can comprise protrusion 143 protruding from the inner (or first) side of top plate 141. In some examples, protrusion 143 can be located generally at the center of the inner side of top plate 141 of lid 140. The thickness of top plate 141 in the region where the protrusion 143 is located can be greater than the thicknesses of other regions of top plate 141.

Lid 140 can comprise a metal. For example, lid 140 can comprise aluminum or copper and have a high thermal conductivity and radiation. In some examples, lid 140 can be referred to as or comprise a heat sink, a heat dissipation plate, or a cap cover. In some examples, trenches, protrusions, or fins can be provided on the outer side of top plate 141 of lid 140 to increase heat dissipation efficiency.

In some examples, the overall height of lid 140 can range from approximately 1 millimeter (mm) to approximately 5 mm. In some examples, the height of protrusion 143, as measured from the inner side of top plate 141, can range from approximately 0.05 mm to approximately 1 mm, and the area of protrusion 143 can range from approximately 0.4 mm by 0.4 mm to approximately 69 mm by 69 mm. The.

Carrier 10 can be a substantially planar plate. In some examples, carrier 10 can comprise or be referred to as a plate, a board, a wafer, a panel, or a strip. In some examples, the thickness of carrier 10 can range from approximately 100 micrometers (μm) to approximately 2000 μm, and the width of carrier 10 can range from approximately 100 mm to approximately 600 mm. Carrier 10 can enable integrated handling of multiple electronic devices in the electronic device manufacturing process.

Carrier 10 can comprise temporary bonding layer 11 provided on the surface of carrier 10. Temporary bonding layer 11 can be provided on the surface of carrier 10 by a coating method such as spin coating, doctor blade coating, casting, painting, spray coating, slot die coating, curtain coating, slide coating, or knife over edge coating, a printing method such as screen printing, pad printing, gravure printing, flexography printing, or offset printing, or an inkjet printing method, or an intermediate technology between coating and printing, or can be provided by direct attachment of a bonding film or bonding tape. In some examples, temporary bonding layer 11 can comprise or be referred to as a temporary bonding film, a temporary bonding tape or a temporary adhesive coating. For example, temporary bonding layer 11 can be a heat release tape or film, or an optical release tape or film, wherein the adhesive strength is weakened or removed by heat or light. Temporary bonding layer 11 can allow the carrier 10 to be separated from lid 140 after the electronic device is completed, as will later be described.

FIG. 2B shows a cross-sectional view of electronic device 100 at a later stage of manufacture. In the example shown in FIG. 2B, adhesive material 130 can be provided in the cavity of lid 140 (e.g., on the inner side of top plate 141). In some examples, adhesive material 130 can be provided to entirely cover or nearly entirely cover the inner side of top plate 141 of lid 140. Adhesive material 130 can comprise or be referred to as a thermal adhesive material, a metallic thermal interface material (TIM), or a polymer TIM. Adhesive material 130 can comprise a thermally conductive material and, with momentary reference to FIG. 1, can contact second side 122 of electronic component 110 and the inner side of the top plate of lid 140. Some examples of adhesive material 130 can include polymer type thermal interface materials such as silicone, epoxy, or urethane, or highly thermal polymer type thermal interface materials such as graphite, boron nitride, silver, aluminum, or aluminum oxide. In some examples, adhesive material 130 can include metal type thermal interface materials such as gallium, gallium alloys, for example alloys with indium, tin, or zinc, silver alloys, tin-silver, indium, or indium alloys.

In some examples, adhesive material 130 can be provided to have patterns or portions spaced apart from each other on the inner side of top plate 141 of lid 140. In some examples, such patterned adhesive material 130 can comprise adhesive pattern 130a and/or adhesive pattern 130b. In some examples, adhesive pattern 130a can be made of different adhesive material as compared to adhesive pattern 130b. In some examples, adhesive pattern 130a can be discontinuous with, or spaced apart from, adhesive pattern 130b. In some examples, the different adhesive patterns can comprise different materials with different properties such as different heat conductivity or heat insulation properties, or different heat dissipation properties. For example, adhesive pattern 130a can be in contact with protrusion 143 and can comprise a metal TIM, and adhesive pattern 130b can be in contact with other regions of lid 140 such as top plate 141 and can comprise a polymer TIM. It should be noted that these are merely examples of the different materials that adhesive pattern 130a and adhesive pattern 130b can comprise, and the scope of the disclosed subject matter is not limited in these respects.

Adhesive material 130 can be applied to the inner side of top plate 141 of lid 140 by, for example, dispensing or printing. In some examples, the thickness of adhesive material 130 can range from approximately 10 μm to approximately 300 μm. Applying adhesive on lid 140 and then locating electronic components 120 and 120′ on adhesive 130 tends to prevent or reduce occurrences of adhesive material 130 from flowing too far along the side walls of electronic components 120 and 120′ or being deformed.

FIG. 2C shows a cross-sectional view of electronic device 100 at a later stage of manufacture. In the example shown in FIG. 2C, electronic components 120 or 120′ can be provided on the upper side of adhesive material 130. In some examples, pick and place equipment can pick up electronic components 120 or 120′, respectively, and place them on the upper side of adhesive material 130. In some examples, pick and place equipment can pick up electronic components 120 or 120′ and place them within the cavity of lid 140. Electronic component(s) 120′ can be seated on the surface of adhesive material 130 applied to the inner side of top plate 141 of lid 140 within the cavity so as to be spaced apart from electronic component 120. The cavity can be defined by sidewalls of lid 140 at the peripheral side of lid 140. Adhesive material 130 on top plate 141 can be provided on, coupled to, and/or contacting second side 122 of electronic components 120 and 120′.

In some examples, electronic component 120 can be attached to protrusion 143 of lid 140 through adhesive material 130. Adhesive material 130 can be positioned between electronic component 120 and top plate 141 of lid 140. Adhesive material 130 can be between second side 122 of electronic component 120 and the lid 140 at protrusion 143. Adhesive material 130 can also be between electronic component 120 and lid 140. In some examples, adhesive material 130 can be between protrusion 143 and sidewall 142. Adhesive material 130 can transfer heat generated from electronic component 120 to lid 140.

Electronic component 120 can comprise first side 121 and second side 122. Second side 122 of electronic component can be opposite first side 121 of electronic component 120. In some examples, first side 121 of electronic component can comprise or be referred to as an active side, and second side 122 of electronic component can comprise or be referred to as an inactive side. Electronic component 120 can comprise side or lateral walls connecting first side 121 of electronic component 120 and second side 122 of electronic component 120. In some examples, electronic component 120 can comprise or be referred to as a die, chip, package, or a passive or active component.

Electronic component 120 can comprise contact pads 123 provided on first side 121 of electronic component 120. Contact pads 123 can be input/output terminals of electronic component 120. Contact pads 123 of electronic component 120 can be spaced apart from each other in a row or column direction. In some examples, contact pads 123 of electronic component 120 can be bond pads of electronic component 120 or a redistribution layer (RDL) pad exposed through a dielectric material of electronic component 120. In some examples, the dielectric material of electronic component 120 can be silicon nitride (SiN) or silicon dioxide (SiO₂).

Electronic component 120 can comprise connectors 124. Connectors 124 can be coupled to and/or in contact with contact pads 123 of electronic component 120. In some examples, connector 124 can comprise or be referred to as a bump, a tin lead (SnPb) bump, a leadfree bump, copper phosphorus (CuP), a stud bump, a pillar, or a post. In some examples, connector 124 can be provided to contact pads 123 of electronic component 120 through electrolytic plating, electroless plating, or sputtering, or deposition such as physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD). In some examples, the thickness of connector 124 can range from approximately 1 μm to approximately 100 μm. In some examples, the overall thickness of electronic component 120 can range from approximately 0.05 mm to approximately 0.8 mm, and the area or “footprint” of electronic component 120 can range from approximately 0.1 mm by 0.1 mm to approximately 100 mm by 100 mm.

In some examples, electronic component 120 can comprise a metallization layer in contact with second side 122 of electronic component 120. In some examples, the metallization layer can comprise or be referred to as a backside metallization (BSM) plating layer, a conductive film, or a conductive membrane.

Electronic component 120′ can include elements, features, materials, or manufacturing methods similar to or the same as those of electronic component 120. Electronic component 120′ can comprise connectors 124′. In some examples, the thickness of electronic component 120′ can be greater than the thickness of electronic component 120. In some examples, when the thickness of electronic component 120′ is similar to the thickness of electronic component 120, top plate 141 of lid 140 may not have protrusion 143 such that top pate 141 can be generally planar and have a uniform thickness.

Electronic component(s) 120′ can be located outside electronic component 120 in a top plane view. For example, electronic component(s) 120′ can be located between electronic component 120 and sidewall 142 of lid 140. Electronic component 120′ can comprise a die, a chip, a package, or a passive or active component. In some examples, electronic component 120′ can comprise or be referred to as a passive component, an antenna, or power device.

FIG. 2D shows a cross-sectional view of electronic device 100 at a later stage of manufacture. In the example shown in FIG. 2D, encapsulant 150 can be provided to fill the cavity of lid 140 and cover electronic components 120 and 120′. Encapsulant 150 can be in contact with or cover the interior sides of sidewalls 142 of lid 140, the upper side of adhesive material 130, and/or the lateral sides of electronic components 120 and 120′. Encapsulant 150 can be positioned between the lateral sides of electronic components 120 and 120′ and sidewalls 142 of lid 140. Encapsulant 150 can transfer heat generated from electronic components 120 and 120′ to lid 140.

In some examples, encapsulant 150 can be provided to fill a space between adjacent lids 140 over carrier 10. Encapsulant 150 can be in contact with or cover the exterior lateral sides of sidewalls 142 of lid 140. In some examples, encapsulant 150 can contact the inner side of top plate 141 of lid 140. For example, encapsulant 150 can be located between adhesive material pattern 130a and adhesive material pattern 130b.

In some examples, encapsulant 150 can comprise or be referred to as a body or a molding. For example, encapsulant 150 can comprise an epoxy mold compound, resin, a filler-reinforced polymer, a B-stage pressed film, or a gel. Encapsulant 150 can be formed by, for example, compression molding, transfer molding, liquid body molding, vacuum lamination, paste printing, or film assist molding.

In some examples, encapsulant 150 can be provided over the upper sides of sidewalls 142 of lid 140 and connectors 124 and 124′ of electronic components 120 and 120′, respectively. An upper portion of encapsulant 150 can be removed to expose the upper side of connectors 124 and 124′ of electronic components 120 and 120′ and the upper sides of the sidewalls 142 of lid 140.

In some examples, the upper portion of encapsulant 150 can be removed by grinding. For example, when removing the upper portion of encapsulant 150, the upper portions of connectors 124 and 124′ of electronic components 120 and 120′ and the upper portions of sidewalls 142 of lid 140 can be removed. In some examples, the upper side of encapsulant 150 can be coplanar with the upper sides of connectors 124 and 124′ of electronic components 120 and 120′ and with the upper sides of sidewalls 142 of lid 140. In some examples, the thickness of encapsulant 150 filling the cavity of lid 140 can range from approximately 50 μm to approximately 1000 μm. Encapsulant 150 can transfer heat generated by electronic components 120, 120′ to lid 140. In some examples, a top side of sidewall 142 can be coplanar with a top side of encapsulant 150 according to the orientation shown in FIG. 2D.

FIG. 2E shows a cross-sectional view of electronic device 100 at a later stage of manufacture. In the example shown in FIG. 2E, substrate 110 can be provided over electronic components 120 and 120′, lid 140, and encapsulant 150. Substrate 110 can comprise dielectric structure 111 and conductive structure 112.

In accordance with various examples, dielectric structure 111 can comprise one or more dielectric layers made of dielectric material (e.g., polymer, polyimide (PI), benzocyclobutene (BCB), polybenzoxazole (PBO), bismaleimide triazine (BT), resin, Ajinomoto Buildup Film (ABF), Si3N4, SiO2, SiON, etc.) and interleaved between layers of conductive structure 112. The thickness of dielectric structure 111 can range from approximately 2 μm to approximately 50 μm. The thickness of dielectric structure 111 can refer to the individual dielectric layers of dielectric structure 111. Conductive structure 112 can comprise one or more conductive layers defining signal distribution elements (e.g., traces, vias, pads, conductive paths, UBMs, etc.). Conductive structure 112 can comprise aluminum, copper, gold, silver, nickel, and/or palladium. The thickness of conductive structure 112 can range from approximately 1 μm to approximately 10 μm. The thickness of conductive structure 112 can refer to individual layers of conductive structure 112. Conductive structure 112 can distribute electrical signals in a vertical direction and a lateral direction through substrate 110. Conductive structure 112 can electrically couple electronic component 120 to electronic component(s) 120′. In some examples, conductive structure 112 can also be coupled to sidewalls 142 of lid 140. Encapsulant 150 can be between substrate 110 and first side 121 of electronic component 120. Encapsulant 150 can cover a lateral side of connector 124.

Conductive structure 112 can comprise substrate internal terminals 112a, substrate external terminals 112b, and one or more conductive layers coupling respective ones of substrate internal terminals 112a to respective ones of substrate external terminals 112b. In some examples, substrate internal terminals 112a can be provided at the inner side of substrate 110 (e.g., at the side proximate or adjacent encapsulant 150 and electronic components 120, 120′). Substrate internal terminals 112a can be coupled to connectors 124, 124′ and sidewalls 142. Substrate external terminals 112b can be provided at the outer side of substrate 110 (e.g., at the side opposite or distal encapsulant 150 and electronic components 120, 120′). In accordance with various examples, substrate 110 can be a redistribution layer (RDL) substrate, and can be formed on encapsulant 150, connectors 124, 124′ and sidewalls 142. Forming substrate 110 over encapsulant 150, electronic components 120, 120′, and sidewalls 142 can reduce package height, as interconnects (e.g., bumps, pillars, adhesive, etc.) between substrate internal terminals 112a and connectors 124, 124 and/or between substrate internal terminals 112a sidewalls 142 can be omitted. Employing an RDL substrate can also allow for substrate internal terminals 112a having a narrower pitch, as compared to pre-formed substrates. While shown as an RDL substrate, it is contemplated and understood that, in some examples, substrate 110 can be a pre-formed or laminate substrate that is formed separately and then disposed over encapsulant 150, connectors 124, 124′, and sidewalls 142.

Dielectric structure 111 can comprise apertures exposing the upper sides of connectors 124 and 124′ and the upper sides of sidewalls 142 of lid 140. For example, after a mask pattern is provided on the upper side of dielectric structure 111, portions of dielectric structure 111 can be removed through etching, to form the apertures and expose the upper sides of connectors 124 and 124′ and sidewalls 142 of lid 140. Conductive structure 112 can be coupled to and in contact with connectors 124 and 124′ and sidewalls 142 exposed through dielectric structure 111. For example, substrate internal terminals 112a can contact connectors 124 and 124′ of electronic components 120 and 120′ and sidewalls 142 of lid 140. In some examples, the overall thickness of substrate 110 can range from approximately 10 μm to approximately 200 μm.

In some examples, a portion of conductive structure 112 that is coupled or in contact with sidewalls 142 of lid 140 can be a conductive structure electrically connected to a ground (e.g., a ground plane in substrate 110 or an external interconnect 160 (FIG. 2F) that will be coupled to ground (e.g., a ground external interconnect).

Substrate 110 is shown as a redistribution layer (“RDL”) substrate in the present example. RDL substrates can comprise one or more conductive redistribution layers and one or more dielectric layers and (a) can be formed layer by layer over an electronic device to where the RDL substrate is to be electrically coupled. RDL substrates can be formed in an additive buildup process and can include one or more dielectric layers alternatingly stacked with one or more conductive layers and define respective conductive redistribution patterns or traces configured to collectively (a) fan-out electrical traces outside the footprint of the electronic device, or (b) fan-in electrical traces within the footprint of the electronic device. The conductive patterns can be formed using a plating process such as, for example, an electroplating process or an electroless plating process. The conductive patterns can comprise an electrically conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process and can include a photolithographic mask through where light is exposed to photo-pattern desired features such as vias in the dielectric layers. The dielectric layers can be made from photo-definable organic dielectric materials such as, for example, PI, BCB, or PBO. Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of one or more inorganic dielectric layers can comprise silicon nitride (Si3N4), silicon oxide (SiO₂), or silicon oxynitride (SiON). The one or more inorganic dielectric layers can be formed by growing the inorganic dielectric layers using an oxidation or nitridization process instead using photo-defined organic dielectric materials. Such inorganic dielectric layers can be filler-fee, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can be referred to as a coreless substrate. Substrates in this disclosure, such as substrate 110, can comprise RDL substrates.

In some examples, substrate 110 can be a pre-formed substrate. Pre-formed substrates can be manufactured prior to attachment to an electronic device and can comprise dielectric layers between respective conductive layers. The conductive layers can comprise copper and can be formed using an electroplating process. The dielectric layers can be relatively thicker non-photo-definable layers and can be attached as a pre-formed film rather than as a liquid and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate and omits the permanent core structure, and the dielectric and conductive layers can be formed on a sacrificial carrier and is removed after formation of the dielectric and conductive layers and before attachment to the electronic device. The pre-formed substrate can be referred to as a printed circuit board (PCB) or a laminate substrate. Such pre-formed substrate can be formed through a semi-additive or modified-semi-additive process. Substrates in this disclosure, such as substrate 110, can comprise pre-formed substrates.

FIG. 2F shows a cross-sectional view of electronic device 100 at a later stage of manufacture. In the example shown in FIG. 2F, external interconnects 160 can be provided over substrate external terminals 112b of substrate 110. External interconnects 160 can be coupled to or in contact with substrate external terminals 112b of substrate 110. In some examples, external interconnects 160 can comprise tin (Sn), silver (Ag), lead (Pb), copper (Cu), tin-lead (Sn—Pb), Sn37-Pb, Sn95-Pb, Sn—Pb—Ag, Sn—Cu, Sn—Ag, Sn—Au, Sn—Bi, or Sn—Ag—Cu. For example, external interconnects 160 can be formed through a reflow process after forming a conductive material containing solder on substrate external terminals 112b using a ball drop method. External interconnects 160 can comprise or be referred to as conductive balls such as solder balls, conductive pillars such as a copper pillars, or conductive posts each having a solder cap formed over a copper pillar. In some examples, the sizes of external interconnects 160 can range from approximately 10 μm to approximately 600 μm. External interconnects 160 can be electrically coupled to electronic components 120 and 120′ through conductive structure 112 of substrate 110.

In some examples, electronic component 170 can be provided on substrate external terminals 112b of substrate 110. Electronic component 170 can be electrically coupled to electronic component 120 and/or electronic component 120′ through conductive structure 112 of substrate 110. Electronic component 170 can include elements, features, materials, or manufacturing methods similar to or the same as those of electronic component 120. Electronic component 170 can comprise a die, a chip, a package, or a passive or active component. In some examples, electronic component 170 can comprise or be referred to as a passive component, an antenna patch, or a power device.

FIG. 2G shows a cross-sectional view of electronic device 100 at a later stage of manufacture. In the example shown in FIG. 2G, carrier 10 can be removed from lid 140 and encapsulant 150. In some examples, the adhesion strength of temporary bonding layer 11 (FIG. 2F) can be removed or reduced by providing heat, light, a chemical solution, or a physical external force, to allow carrier 10 to be separated from lid 140 and the lower side of encapsulant 150. In response to removal of carrier 10, the outer side of top plate 141 of lid 140 can be exposed.

In accordance with various examples, a singulation process can be performed where encapsulant 150 and substrate 110 interposed between spaced-apart lids 140 are separated into individual electronic devices 100 by sawing. In some examples, during the singulation process, a diamond blade or a laser beam can be utilized. In some examples, after singulation, the exterior lateral sides of sidewalls 142 of lid 140 can be exposed and uncovered by encapsulant 150 and the lateral sides of sidewalls 142 can be coplanar with the lateral sides of substrate 110. Electronic device 100 can comprise substrate 110, electronic component 120, electronic component(s) 120′, adhesive material 130, lid 140, encapsulant 150, and external interconnects 160. Electronic components 120 and 120′ can be surrounded by encapsulant 150, and encapsulant 150 can be surrounded by lid 140. As shown in FIG. 2G, as a result of the singulating process, encapsulant 150 can be removed from the exterior lateral sides of lid 140, and the lateral sides of substrate 110 can be flush or coplanar with the exterior lateral sides of lid 140. For example, the exterior lateral side of sidewall 142 can be uncovered by encapsulant 150. In some examples, conductive structure 112 can be exposed at the lateral sides of substrate 110, and in other examples conductive structure 112 can be covered by dielectric structure 111 of substrate 110 at the lateral sides of substrate 110.

Electronic device 100 can be flipped about substrate 110 such that external interconnects 160 are located on the lower side of substrate 110, and electronic components 120 and 120′, adhesive material 130, lid 140, and encapsulant 150 are located on the upper side of substrate 110. In some examples, electronic device 100 can have electronic component 170 located on the lower side of substrate 100.

FIG. 2H shows a cross-sectional view of electronic device 100′. In the example shown in FIG. 2H, a singulation process that is different than the singulation process of FIG. 2G can be used to provide individual electronic devices 100′. The singulation process of FIG. 2H can leave an external portion of encapsulant 150 on the exterior lateral sides of sidewall 142 of lid 140. In addition, a portion of substrate 110 can extend beyond the exterior lateral sides of lid 140 and can be flush or coplanar with the external portion of encapsulant 150. As a result, the exterior lateral sides of sidewall 142 of lid 140 can be covered by encapsulant 150. In some examples, conductive structure 112 can be exposed from the lateral sides of substrate 110, and in other examples conductive structure 112 can be covered by dielectric structure 111 of substrate 110 at the lateral sides of substrate 110.

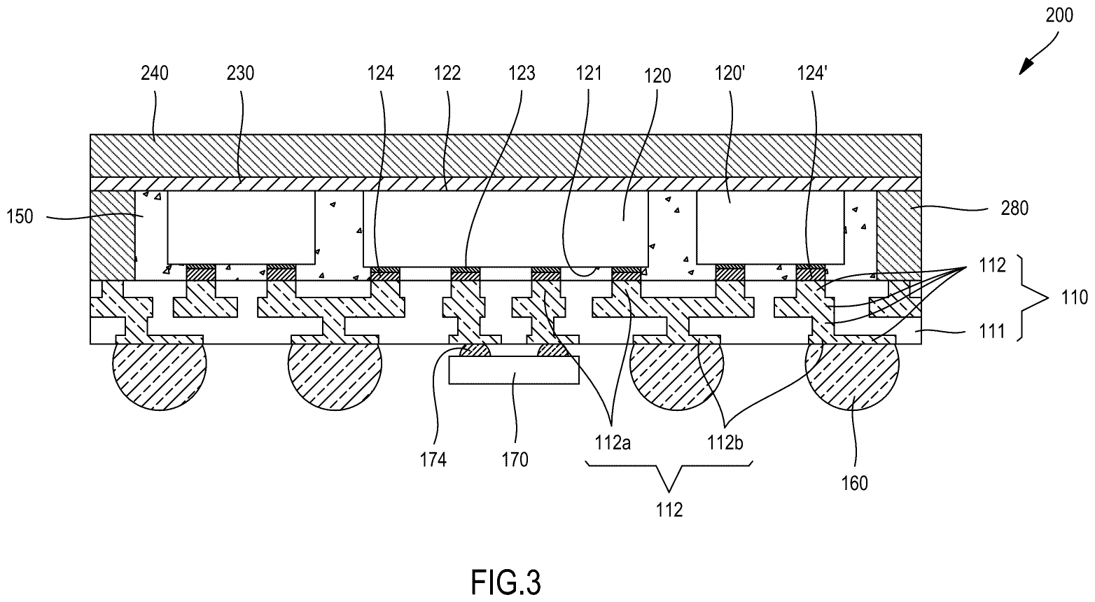

FIG. 3 shows a cross-sectional view of an example electronic device 200. In the example shown in FIG. 3, electronic device 200 can comprise substrate 110, electronic components 120 and 120′, encapsulant 150, external interconnects 160, adhesive material 230, lid 240, and posts 280. In some examples, electronic device 200 can further comprise electronic component 170. In some examples, post 280 can directly contact conductive structure 112 or can directly contact dielectric structure 111. In some examples, post 280 can be coupled with conductive structure 112 or can be coupled with dielectric structure 111. In some examples, a bottom side of post 280 can be coplanar with a bottom side of encapsulant 150, and a top side of conductive structure 112 can be coplanar the bottom side of post 280. In some examples, a bottom side of post 280 can be coplanar with a top side of dielectric structure 111. In some examples, adhesive material 230 can be between the top side of post 280 and the inner side of lid 240. Encapsulant 150 can cover an internal lateral side of post 280, and the exterior lateral side of post 280 can be uncovered by encapsulant 150.

Electronic device 200 can be similar to electronic device 100. For example, electronic device 200 can be similar to electronic device 100 in terms of substrate 110, electronic component 120, electronic component 120′, electronic component 170, encapsulant 150, and external interconnects 160. Lid 240 of electronic device 200 can be in the configuration shown in FIG. 3 in contrast to the configuration of lid 140 as shown in FIG. 1.

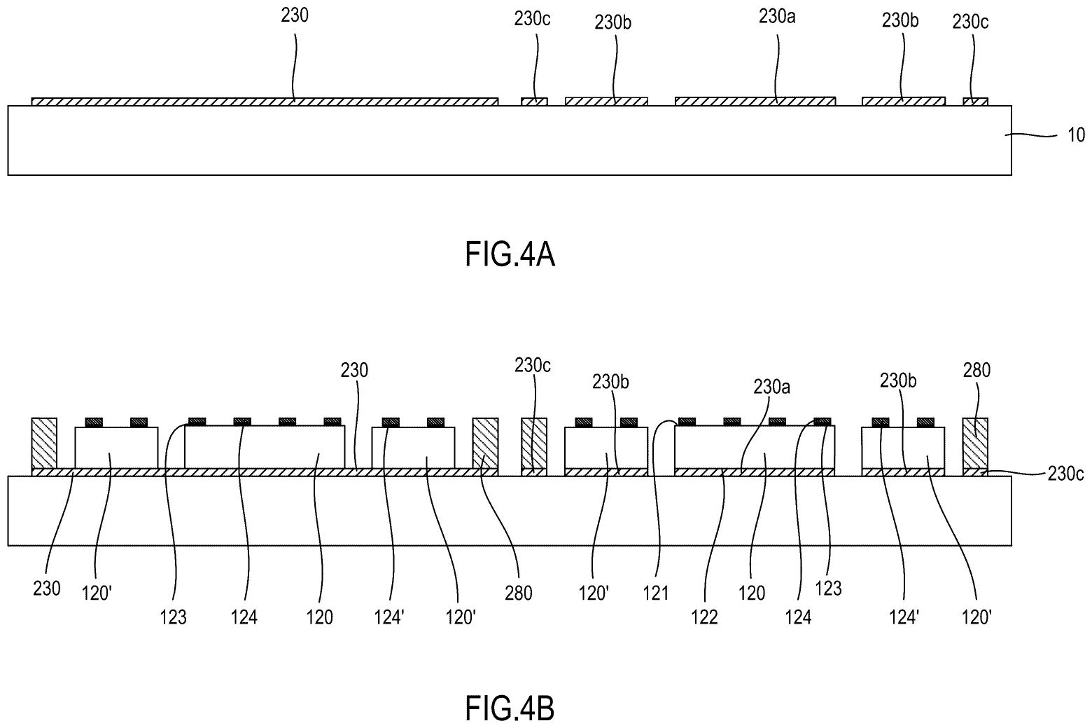

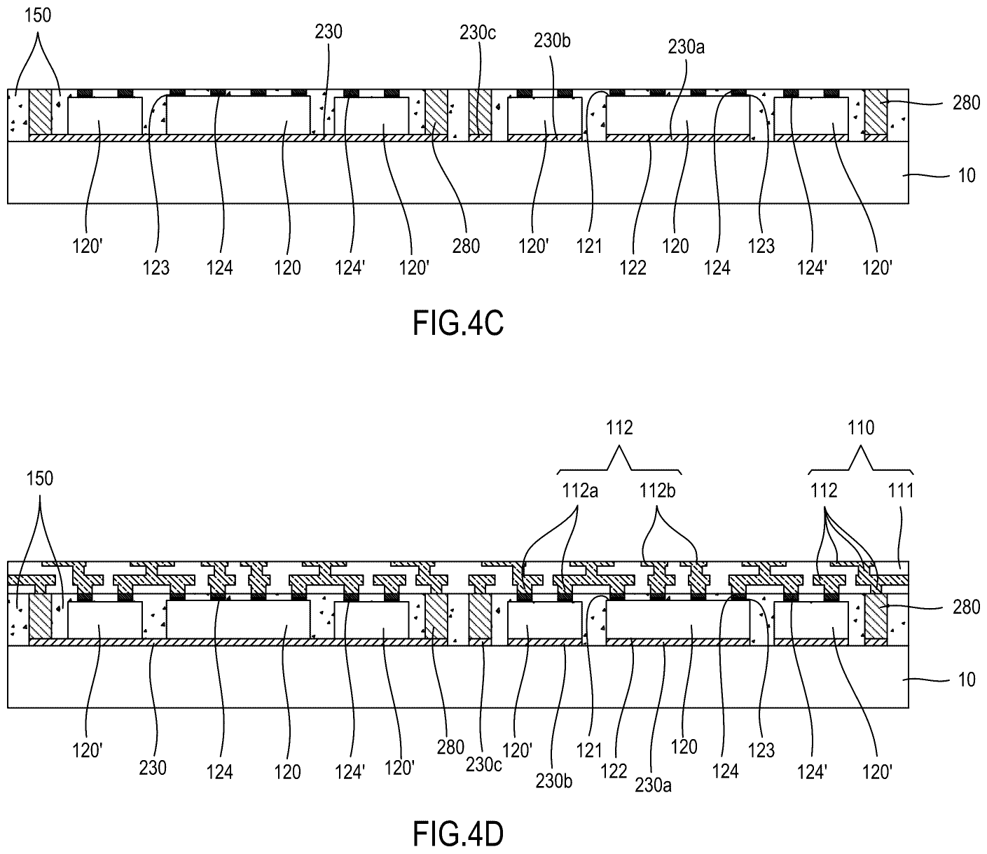

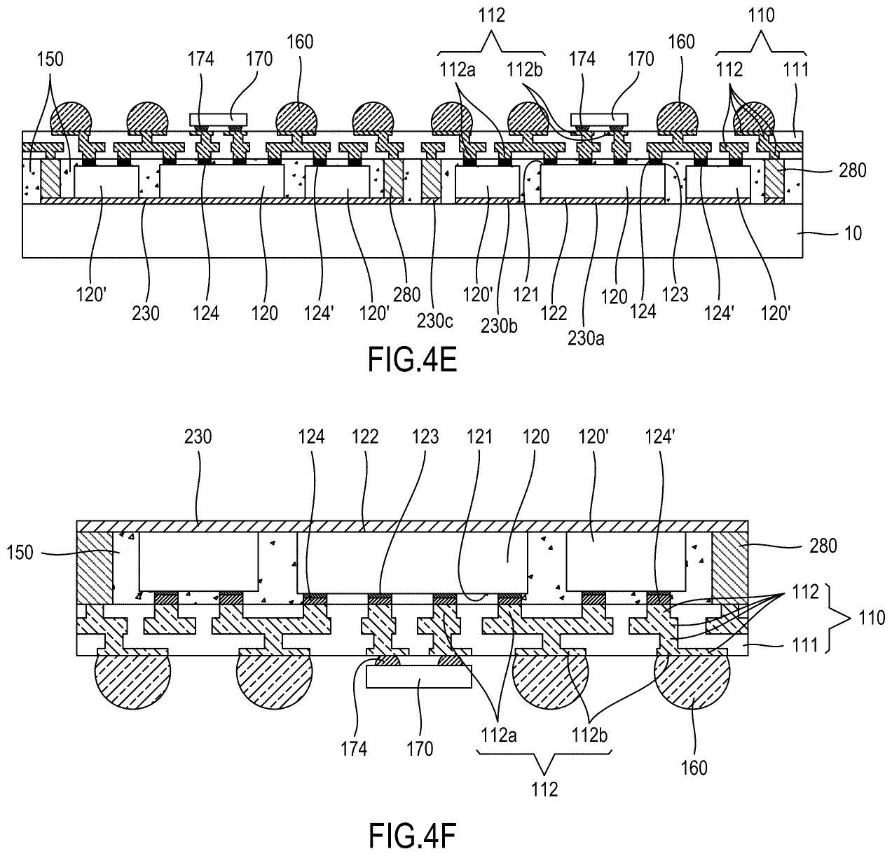

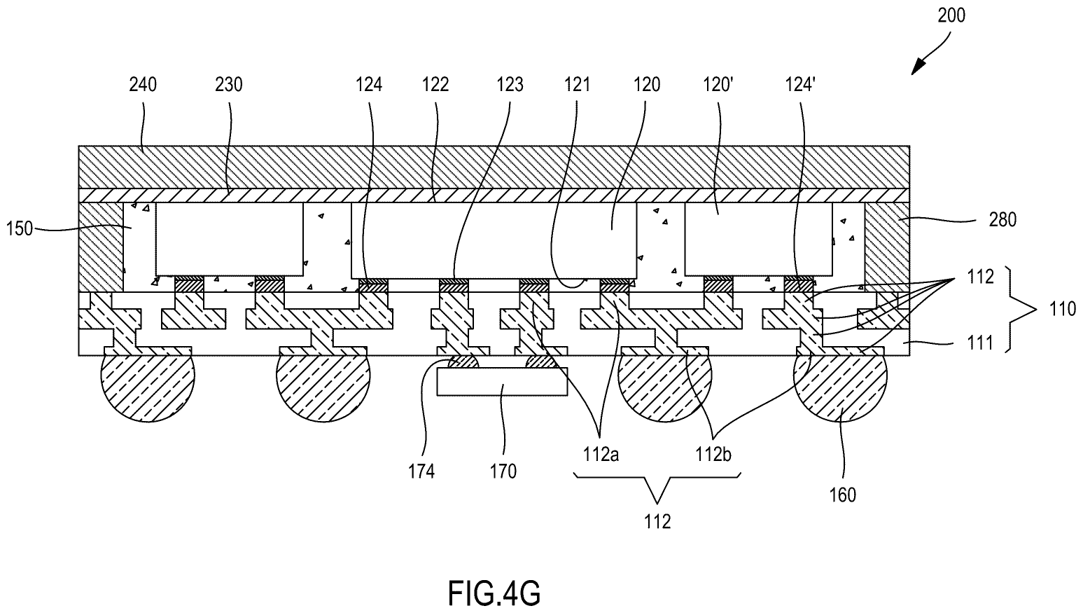

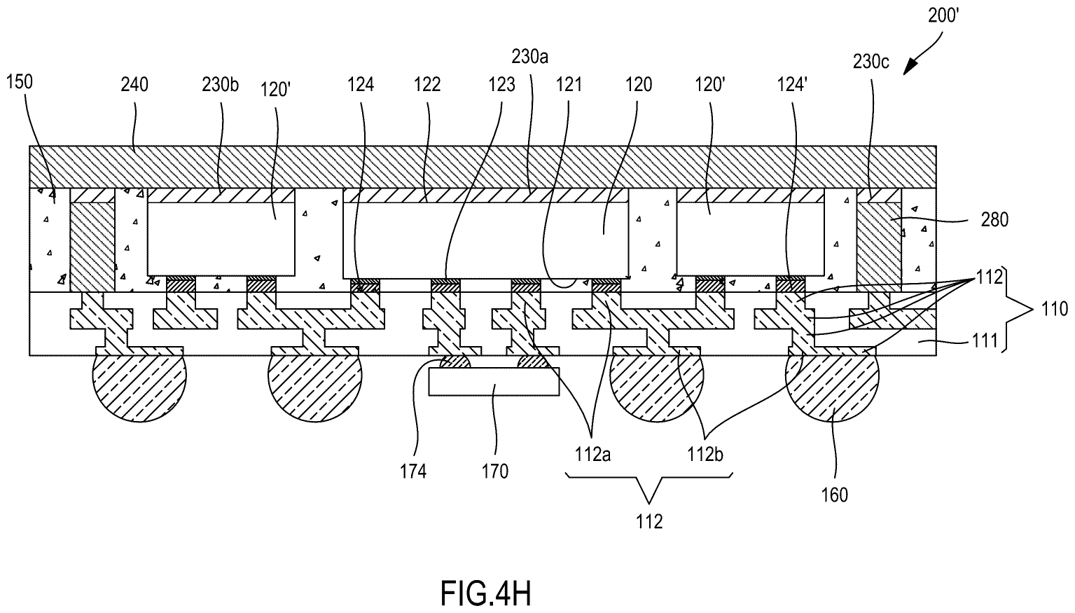

FIGS. 4A to 4H show cross-sectional views of an example method for manufacturing an example electronic device, such as electronic device 200 in FIG. 3. FIG. 4A shows a cross-sectional view of electronic device 200 at an early stage of manufacture. In the example shown in FIG. 4A, adhesive material 230 can be provided on the surface of carrier 10. Adhesive material 230 can be in contact with the upper side of carrier 10. Adhesive material 230 can include elements, features, materials, or manufacturing methods similar to, or the same as, those of adhesive material 130 of electronic device 100. In some examples, carrier 10 used in the manufacture of electronic device 200 can comprise temporary bonding layer 11.

In some examples, adhesive material 230 can cover the entire surface of carrier 10. In other examples, adhesive material 230 can be provided at locations over carrier 10 where each electronic device 200 is to be provided. In some examples, adhesive material 230 can be provided at locations where electronic components 120, electronic components 120′ and/or posts 280 are to be provided. Since adhesive material 230 is provided on carrier 10, it is possible to prevent or reduce occurrences of adhesive material 230 flowing down along the lateral sides of electronic components 120 and 120′ or deforming due to being provided on the upper sides of electronic components 120 and 120′. In some examples, adhesive material 230 can comprise adhesive patterns such as adhesive pattern 230a, adhesive pattern 230b, and adhesive pattern 230c. In some examples, adhesive pattern 230a, adhesive pattern 230b, or adhesive pattern 230c can be made of different adhesive materials. In some examples, the different adhesive patterns can comprise different materials with different properties such as different heat conductivity or heat insulation properties, or different heat dissipation properties. For example, adhesive pattern 230a can comprise a metal TIM, adhesive pattern 230b can comprise a polymer TIM, and adhesive pattern 230c can comprise a carbon filled TIM. It should be noted that these are merely examples of the different materials that adhesive pattern 230a, adhesive pattern 230b, and adhesive pattern 230c can comprise, and the scope of the disclosed subject matter is not limited in these respects.

FIG. 4B shows a cross-sectional view of electronic device 200 at a later stage of manufacture. In the example shown in FIG. 4B, electronic components 120 and 120′ and posts 280 can be provided on adhesive material 230. Electronic components 120 and 120′ and posts 280 can be coupled to carrier 10 through adhesive material 230. Electronic components 120 and 120′ can include elements, features, materials, or manufacturing methods similar to or the same as those of electronic components 120 and 120′ of electronic device 100.

Pick and place equipment can pick up posts 280 and seat them on the upper side of adhesive material 230. In some examples, posts 280 can be provided over carrier 10 in a square or rectangular ring shape in top plan view and can surround electronic components 120 and 120′. In some examples, posts 280 can be located in the four corner regions about electronic components 120 and 120′. The interior lateral sides of posts 280 can face electronic components 120 and 120′ and exterior lateral sides of posts 280 can face the adjacent posts 280. Adhesive material 230 can couple the first (or lower) sides of posts 280 to carrier 10. Posts 280 can provide a cavity, and electronic components 120 and 120′ can be located within the cavity. Posts 280 can be provided on carrier 10 so as to be spaced apart from each other to have rows or columns. Posts 280 can be made of metal. For example, posts 280 can be made of copper, gold, silver, palladium, or nickel. In some examples, the widths of each post 280 can range from approximately 0.2 mm to approximately 2 mm, and the height of each post 280 can range from approximately 0.2 mm to approximately 4 mm.

FIG. 4C shows a cross-sectional view of electronic device 200 at a later stage of manufacture. In the example shown in FIG. 4C, encapsulant 150 can cover posts 280 and electronic components 120 and 120′. Encapsulant 150 contact the lateral sides of posts 280, the upper side of adhesive material 230, and the lateral sides of electronic components 120 and 120′. Encapsulant 150 can be in contact with the interior lateral sides of posts 280 and can fill the cavity generally defined by posts 280. Encapsulant 150 can transfer heat generated from the electronic components 120 and 120′ to posts 280. In some examples, encapsulant 150 can contact the upper side of carrier 10. Encapsulant 150 can expose the upper sides of connectors 124, 124′ of electronic components 120, 120′ and the upper sides of posts 280. The upper side of encapsulant 150 can be coplanar with the upper sides of connectors 124 and 124′ and the upper sides of posts 280. Elements, features, materials, or manufacturing methods of encapsulant 150 can be the same as or similar to those of encapsulant 150 of electronic device 100. In some examples, a top side of post 280 can be coplanar with a top side of encapsulant 150 according to the orientation shown in FIG. 4C.

FIG. 4D shows a cross-sectional view of electronic device 200 at a later stage of manufacture. In the example shown in FIG. 4D, substrate 110 can be provided to cover electronic components 120 and 120′, posts 280, and encapsulant 150. Substrate 110 can comprise dielectric structure 111 and conductive structure 112. Elements, features, materials, or manufacturing methods of substrate 110 can be the same as or similar to those of substrate 110 of electronic device 100.

FIG. 4E shows a cross-sectional view of electronic device 200 at a later stage of manufacture. In the example shown in FIG. 4E, external interconnects 160 can be provided at substrate external terminals 112b of substrate 110. In some examples, electronic component 170 can be provided on substrate external terminals 112b of substrate 110. Elements, features, materials, or manufacturing methods of external interconnects 160 and electronic component 170 can be the same as or similar to those of external interconnects 160 and electronic component 170, respectively, of electronic device 100.

FIG. 4F shows a cross-sectional view of electronic device 200 at a later stage of manufacture. In the example shown in FIG. 4F, carrier 10 can be removed from adhesive material 230 and encapsulant 150. In some examples, carrier 10 can be removed by grinding. In some examples, carrier 10 can be removed by reducing the adhesive strength of a temporary bonding layer, as described above with reference to carrier 10 and temporary bonding layer 11 of electronic device 100. Carrier 10 can be removed to expose the upper side of adhesive material 230 and the upper side of encapsulant 150. After removing carrier 10, a singulation process can be performed where encapsulant 150 and substrate 110 interposed between spaced-apart posts 280 are separated into individual electronic devices 200 by sawing. In some examples, during the singulation process, a diamond blade or a laser beam can be utilized. In some examples, the exterior lateral sides of posts 280 can be exposed through the singulation process such that the exterior lateral sides of posts are uncovered by encapsulant 150. In some examples, a portion of the exterior lateral side of encapsulant 150 can be located between adjacent posts, and the exterior lateral side of encapsulant 150 can be flush or coplanar with the exterior lateral sides of posts 280. The exterior lateral sides of posts 280 can be flush or coplanar with the lateral sides of substrate 110.

Individually separated electronic devices 200 can be flipped about substrate 110 such that external interconnects 160 are located on the lower side of substrate 110, and electronic components 120 and 120′, adhesive material 230, encapsulant 150, and posts 280 are located on the upper side of substrate 110. In some examples, electronic device 200 can have electronic component 170 located on the lower side of substrate 100. Adhesive material 230 can be in contact with the upper sides of electronic components 120 and 120′, the upper side of encapsulant 150, and the upper sides of posts 280.

FIG. 4G shows electronic device 200 at a later stage of manufacture. In the example shown in FIG. 4G, lid 240 can be attached to cover the upper side of adhesive material 230. In some examples, lid 240 can comprise a rectangular plate. Lid 240 can be coupled to electronic components 120 and 120′, encapsulant 150, and posts 280 through adhesive material 230. Elements, features, materials, or manufacturing methods of lid 240 can be similar to those of top plate 141 of lid 140 of electronic device 100. In some examples, the inner side of lid 240 can be planar (e.g., lid 240 can be devoid of protrusion(s)). Adhesive material 230 can transfer heat generated from electronic components 120 and 120′ to lid 240. Encapsulant 150 can transfer heat generated from electronic components 120 and 120′ to posts 280. Electronic device 200 can comprise substrate 110, electronic component 120, electronic component(s) 120′, and electronic component 170, adhesive material 230, lid 240, encapsulant 150, external encapsulant 160, and posts 280. Electronic components 120 and 120′ can be surrounded by encapsulant 150.

FIG. 4H shows electronic device 200′. In the example shown in FIG. 4H, a singulation process that is different than the singulation process of FIG. 4F can be used to provide individual electronic devices 200′. The singulation process of FIG. 4H can leave an external portion of encapsulant 150 on the exterior lateral sides of posts 280. In addition, a portion of substrate 110 can extend beyond the exterior lateral side of posts 280 and can be flush or coplanar with the external portion of encapsulant 150. Similarly, a portion of lid 240 can extend beyond the exterior lateral sides of posts 280 and can be flush or coplanar with the external portion of encapsulant 150. As a result, the exterior lateral sides of posts 280 can be covered by encapsulant 150, and an external portion of encapsulant 150 can be between the inner side of lid 240 and the top side of substrate 110 at the outer perimeter of substrate 110. In some examples, encapsulant 150 can contact the inner side lid 240 and the lateral sides of adhesive patterns 230a, 230b, 230c. While electronic device 200′ is shown having adhesive patterns 230a, 230b, 230c, it is contemplated and understood that in some examples, electronic device 200′ can include a continuous adhesive 230, similar to electronic device 200 in FIG. 4G. Similarly, it is contemplated and understood that in some examples, electronic device 200 can include adhesive patterns 230a, 230b, 230c, similar to electronic device 200′ in FIG. 4H. In some examples, conductive structure 112 can be exposed at the lateral sides of substrate 110, and in other examples conductive structure 112 can be covered by dielectric structure 111 of substrate 110 at the lateral sides of substrate 110. In some examples, post 280 can directly contact conductive structure 112 or can directly contact dielectric structure 111. In some examples, post 280 can be coupled with conductive structure 112 or can be coupled with dielectric structure 111. In some examples, a bottom side of post 280 can be coplanar with a bottom side of encapsulant 150, and a top side of conductive structure 112 can be coplanar the bottom side of post 280. In some examples, a bottom side of post 280 can be coplanar with a top side of dielectric structure 111.

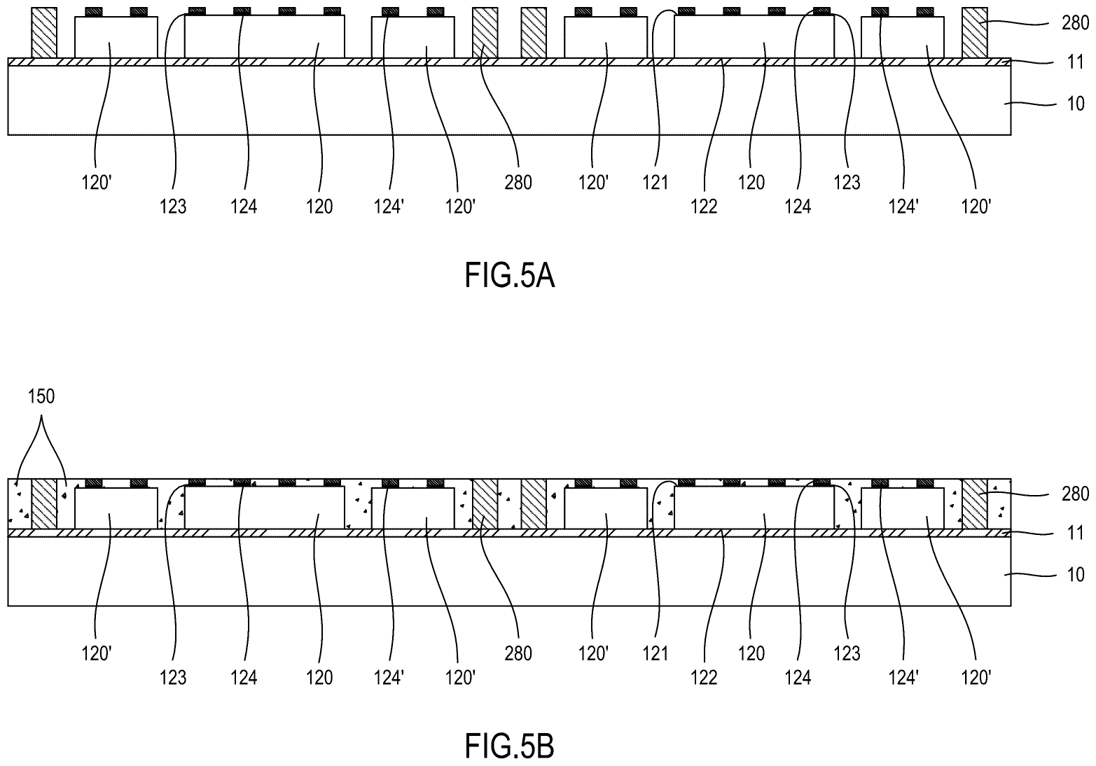

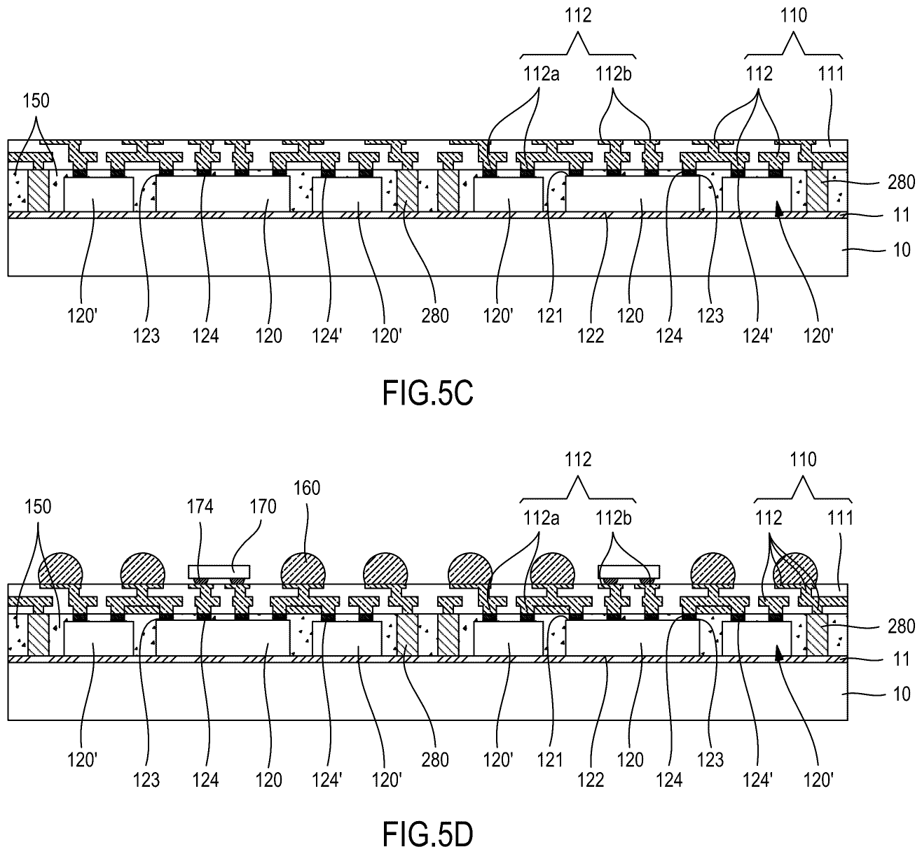

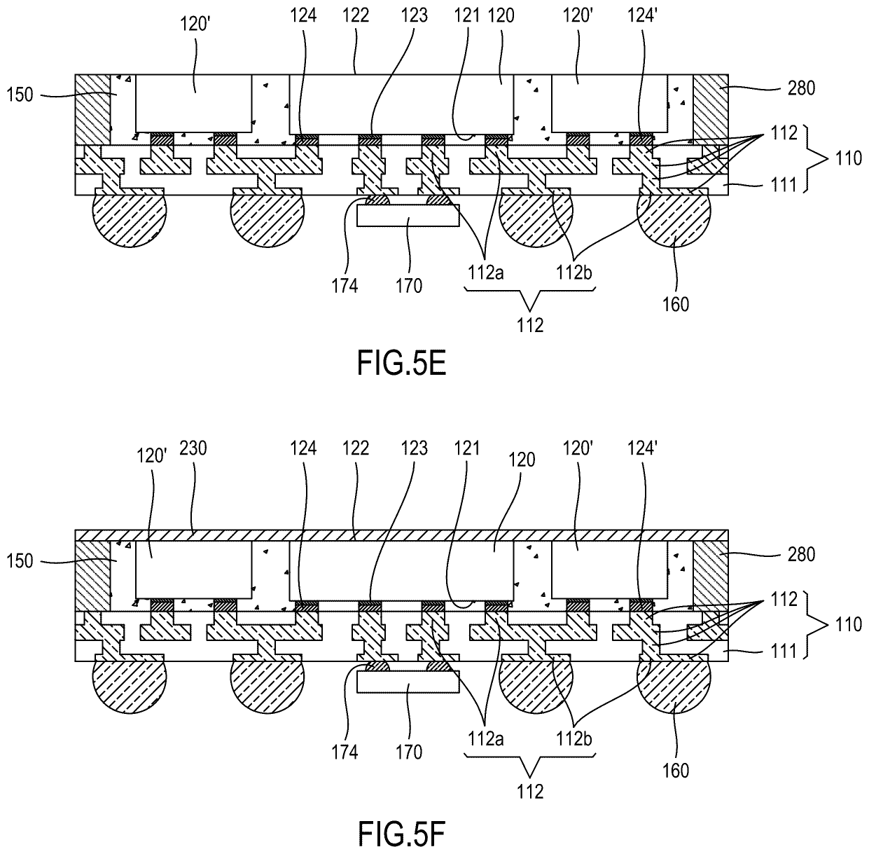

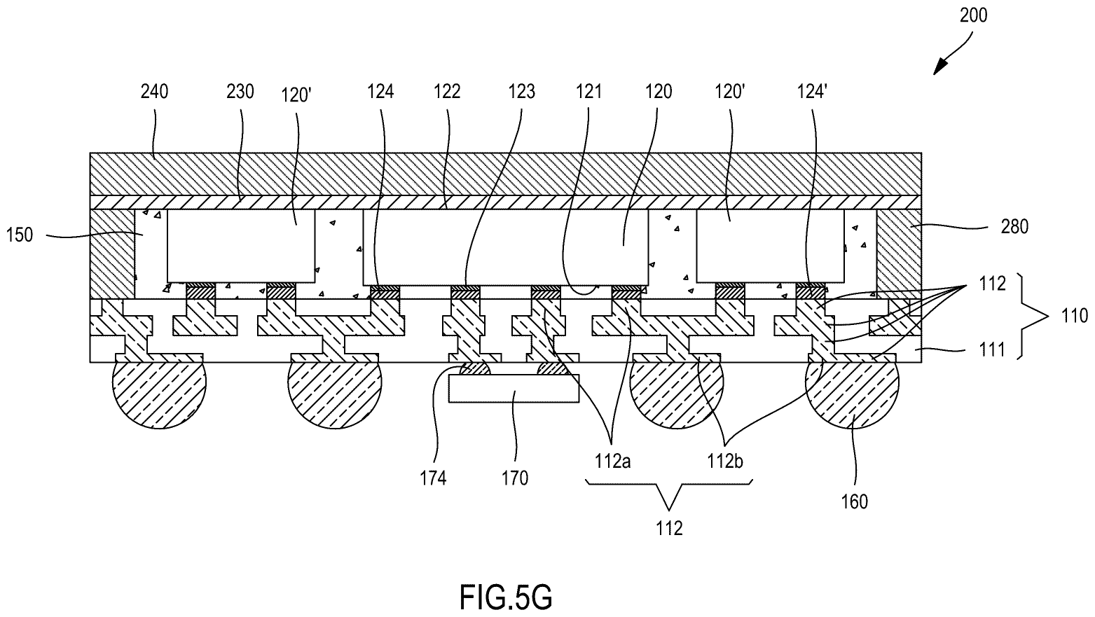

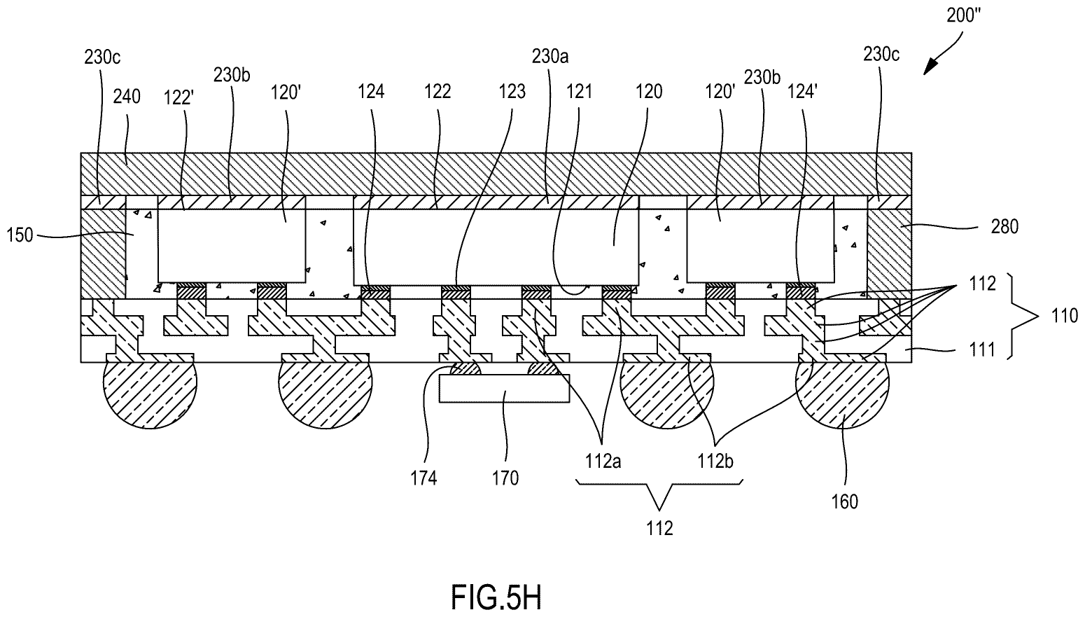

FIGS. 5A to 5H show cross-sectional views of an example method for manufacturing example electronic device 200. FIG. 5A shows a cross-sectional view of electronic device 200 at an early stage of manufacture. In the example shown in FIG. 5A, electronic components 120 and 120′ and posts 280 can be provided on the upper side of carrier 10. Carrier 10 can comprise temporary bonding layer 11 provided on the upper side. Electronic components 120 and 120′ and posts 280 can be coupled to carrier 10 through temporary bonding layer 11. The elements, features, materials, or manufacturing methods of electronic components 120 and 120′ can be similar to or the same as those of electronic component 120 and 120′ of electronic device 100. The method of providing posts 280 can be similar to the method of providing posts 280 shown in FIG. 4B.

FIGS. 5B to 5D show cross-sectional views of example electronic device 200 at a later stage of manufacture. The example shown in FIGS. 5B, 5C and 5D can be similar to the process of manufacturing electronic device 200 shown in FIGS. 4C, 4D, and 4E, respectively.

FIG. 5E shows a cross-sectional view of electronic device 200 at a later stage of manufacture. In the example shown in FIG. 5E, carrier 10 can be removed from electronic components 120 and 120′, encapsulant 150, and posts 280. The method of removing carrier 10 can be similar to the method of removing carrier 10 of electronic device 100. Carrier 10 can be removed to expose the top of the electronic devices 120 and 120′, the top of the encapsulant 150, and the top of the posts 280. After the carrier 10 is removed, a singulation process can be performed where encapsulant 150 and the area of substrate 110 located between adjacent posts 280 of separate electronic device 200 are separated into individual electronic devices 200 by sawing. The singulation process can be similar to the singulation process in FIG. 4F.

Singulated electronic devices 200 can be flipped so, on the basis of substrate 110, external interconnects 160 are located on the lower side of substrate 110, and electronic components 120 and 120′, encapsulant 150, and posts 280 are located on the upper side of substrate 110. In some examples, electronic device 200 can have electronic component 170 located on the lower side of substrate 100.

FIG. 5F shows a cross-sectional view of electronic device 200 at a later stage of manufacture. In the example shown in FIG. 5F, adhesive material 230 can be provided to over and/or covering electronic components 120 and 120′, encapsulant 150, and posts 280. Adhesive material 230 can be in contact with the upper sides of electronic devices 120 and 120′, the upper side of encapsulant 150, and the upper sides of posts 280. The elements, features, materials, or manufacturing methods of adhesive 230 can be similar to or the same as those of adhesive material 130 of electronic device 100.

FIG. 5G shows a cross-sectional view of electronic device 200 at a later stage of manufacture. In the example shown in FIG. 5G lid 240 is located over and coupled to adhesive 230. The example shown in FIG. 5G can be similar to the manufacturing process shown in FIG. 4G. In some examples, the electronic device 200 of FIG. 5G is substantially similar or identical to electronic device 200 of FIG. 4G. In some examples, a different singulation process can be used similar to the singulation process used for the electronic device 200′ of FIG. 4H to arrive at an electronic device 200 as shown in FIG. 5G but with external portions of encapsulant 150 covering the exterior lateral sides of posts 280. In such examples, a portion of substrate 110 can extend beyond the exterior lateral side of posts 280 and can be flush or coplanar with the external portion of encapsulant 150. Similarly, a portion of lid 240 and adhesive 230 can extend beyond the exterior lateral sides of posts 280 and can be flush or coplanar with the external portion of encapsulant 150. As a result, the exterior lateral sides of posts 280 can be covered by encapsulant 150. In some examples, conductive structure 112 can be exposed at the lateral sides of substrate 110, and in other examples conductive structure 112 can be covered by dielectric structure 111 at the lateral sides of substrate 110.

FIG. 5H shows a cross-sectional view of electronic device 200″ at a later stage of manufacture. The example shown in FIG. 5H can be substantially similar to the electronic device 200 of FIG. 5G except that adhesive material 230 can be provided as adhesive pattern 230a disposed between an inner (or bottom) side of lid 240 and top side 122 of electronic component 120, adhesive patterns 230b disposed between the inner (or bottom) side of lid 240 and top side 122′ of electronic component 120′, and adhesive pattern 230c between the inner (or bottom) side of lid 240 and the top sides of posts 280. In such examples, since adhesive patterns 230a, 230b, and 230c are not continuous across the inner side of lid 240, a gap may exist between the lateral sides of adjacent adhesive patterns 230a, 230b, and 230c and between the inner (or bottom) side of lid 240 and the top side of encapsulant 150. Such a gap may comprise an air gap or can be filled with another material, for example overflow of the adhesive of adhesive patterns 230a, 230b, or 230c. In some examples, the different adhesive patterns can comprise different materials with different properties such as different heat conductivity or heat insulation properties, or different heat dissipation properties. For example, adhesive pattern 230a can comprise a metal TIM, adhesive pattern 230b can comprise a polymer TIM, and adhesive pattern 230c can comprise a carbon filled TIM. It should be noted that these are merely examples of the different materials that adhesive pattern 230a, adhesive pattern 230b, and adhesive pattern 230c can comprise, and the scope of the disclosed subject matter is not limited in these respects. In some examples, post 280 can directly contact conductive structure 112 or can directly contact dielectric structure 111. In some examples, post 280 can be coupled with conductive structure 112 or can be coupled with dielectric structure 111. In some examples, a bottom side of post 280 can be coplanar with a bottom side of encapsulant 150, and a top side of conductive structure 112 can be coplanar the bottom side of post 280. In some examples, a bottom side of post 280 can be coplanar with a top side of dielectric structure 111.

The present disclosure includes reference to certain examples. However, it will be understood by those skilled in the art that various changes may be made and equivalents may be substituted without departing from the scope of the disclosure. In addition, modifications can be made to the disclosed examples without departing from the scope of the present disclosure. Therefore, it is intended that the present disclosure not be limited to the examples disclosed, but that the disclosure will include all examples falling within the scope of the appended claims.

1. An electronic device, comprising:
a substrate comprising a top side, a bottom side, a dielectric structure, and a conductive structure;
a first electronic component over the top side of the substrate and coupled with the conductive structure, wherein the first electronic component comprises a first side facing the substrate and a second side facing away from the substrate;
an encapsulant over the top side of the substrate and covering a lateral side of the first electronic component;
a lid over the top side of the substrate and over the first electronic component; and
an adhesive between the second side of the first electronic component and an inner side of the lid.

2. The electronic device of claim 1, comprising a connector between the conductive structure and a contact pad on the first side of the first electronic component, wherein the first electronic component is coupled with the conductive structure through the connector.

3. The electronic device of claim 2, wherein the encapsulant is between the top side of the substrate and the first side of the first electronic component and covers a lateral side of the connector.

4. The electronic device of claim 1, wherein the lid comprises a protrusion on the inner side of the lid, and the adhesive is disposed between the second side of the first electronic component and the protrusion.

5. The electronic device of claim 1, comprising a second electronic component over the top side of the substrate and coupled with the conductive structure, wherein the adhesive is disposed between a top side of the second electronic component and the inner side of the lid.

6. The electronic device of claim 5, wherein the lid comprises a protrusion on the inner side of the lid and a sidewall at a peripheral side of the lid, and the adhesive is between the top side of the second electronic component and the inner side of the lid and between the protrusion and the sidewall.

7. The electronic device of claim 5, wherein:
the adhesive comprises a first adhesive pattern and a second adhesive pattern:
the first adhesive pattern is between the second side of the first electronic component and the inner side of the lid;
the second adhesive pattern is between the top side of the second electronic component and the inner side of the lid; and
the first adhesive pattern is discontinuous with the second adhesive pattern.

8. The electronic device of claim 7, wherein the first adhesive pattern comprises a first adhesive material and the second adhesive pattern comprises a second adhesive material different than the first adhesive material.

9. The electronic device of claim 1, wherein the lid comprises a sidewall at a peripheral side of the lid, and an exterior lateral side of the sidewall is uncovered by the encapsulant.

10. The electronic device of claim 1, wherein the lid comprises a sidewall at a peripheral side of the lid, and an exterior lateral side of the sidewall is covered by a portion of the encapsulant.

11. The electronic device of claim 1, comprising a post over the top side of the substrate, wherein the adhesive is between a top side of the post and the inner side of the lid.

12. The electronic device of claim 11, wherein an exterior lateral side of the post is uncovered by the encapsulant.

13. The electronic device of claim 11, wherein an exterior lateral side of the post is covered by a portion of the encapsulant.

14. The electronic device of claim 13, wherein the portion of the encapsulant is between the inner side of the lid and the top side of the substrate.

15. A method to manufacture an electronic device, comprising:
providing a lid comprising a first side and a second side;
providing an adhesive on the first side of the lid;
providing a first electronic component on the first side of the lid on the adhesive;
providing an encapsulant on the first side of the lid and covering a lateral side of the first electronic component; and
providing a substrate over the encapsulant, over the first electronic component, and over the lid, wherein the substrate comprises a dielectric structure and a conductive structure, and wherein the first electronic component is coupled with the conductive structure.

16. The method of claim 15, wherein the lid comprises a top plate and a sidewall extending from the top plate, and the sidewall is coupled with the substrate.

17. The method of claim 15, comprising providing a connector between the conductive structure and the first electronic component, wherein the encapsulant is between the substrate and the first electronic component and covers a lateral side of the connector.

18. A method to manufacture an electronic device, comprising:
providing an adhesive;
providing a first electronic component on the adhesive;
providing a post on the adhesive;
providing an encapsulant between the post and the first electronic component, wherein the encapsulant covers a lateral side of the first electronic component and an interior lateral side of the post;
providing a substrate over the encapsulant, over the first electronic component, and over the post, wherein the substrate comprises a dielectric structure and a conductive structure, and wherein first electronic component is coupled with the conductive structure; and
providing a lid over the encapsulant, over the first electronic component, and over the post, wherein the adhesive is between the first electronic component and the lid.

19. The method of claim 18, wherein the adhesive comprises a first adhesive pattern and a second adhesive pattern, the first adhesive pattern is between the first electronic component and the lid, and the second adhesive pattern is between the post and the lid.

20. The method of claim 18, comprising providing a connector between the conductive structure and the first electronic component, wherein the encapsulant is between the substrate and the first electronic component and covers a lateral side of the connector.
